(19) United States
(12) Patent Application Publication
(10) Pub. No.: US 2026/0164550 A1
(43) Pub. Date: Jun. 11, 2026

(54) SUBSTRATE COMPRISING NANOTWIN METAL LAYER AND PRINTED CIRCUIT BOARD

(71) Applicant: SAMSUNG ELECTRO-MECHANICS CO., LTD., Suwon-si (KR)

(72) Inventors: Seong Hun NA, Suwon-si (KR); Sung HAN, Suwon-si (KR); Jeong A KIM, Suwon-si (KR); Sang Ik CHO, Suwon-si (KR)

(73) Assignee: SAMSUNG ELECTRO-MECHANICS CO., LTD., Suwon-si (KR)

(21) Appl. No.: 19/324,404

(22) Filed: Sep. 10, 2025

(30) Foreign Application Priority Data
Dec. 10, 2024 (KR) 10-2024-0182714

(51) Int. Cl. H05K 1/09

(52) U.S. Cl. CPC H05K 1/09; H05K 2201/0338; H05K 2201/0364

(57) ABSTRACT

A substrate including a nanotwin metal layer and a printed circuit board formed using the same are provided, the substrate including a seed layer disposed on the substrate and a nanotwin copper layer disposed on the seed layer, wherein the seed layer includes a crystal structure having a random orientation, a crystal structure having a preferred orientation on a (200) plane, and/or a crystal structure having a preferred orientation on a (220) plane.

### CROSS-REFERENCE TO RELATED APPLICATIONS

This application claims benefit of priority to Korean Patent Application No. 10-2024-0182714 filed on Dec. 10, 2024 in the Korean Intellectual Property Office, the disclosure of which is incorporated herein by reference in its entirety.

### BACKGROUND

### 1. Field

The present disclosure relates to a substrate including a nanotwin metal layer and a printed circuit board formed using the substrate including the nanotwin metal layer.

### 2. Description of Related Art

Recently, as high-performance products such as artificial intelligence chips or substrates for servers, have emerged, more input/output terminals are required to implement high performance, and accordingly, implementing a fine pitch in components may be required. For example, implementing a fine pitch in microbumps formed in a mounting region of a semiconductor chip on a package substrate may be required. In addition, as power increases, high-temperature operation reliability is required before and after mounting of semiconductor chips.

### SUMMARY

An aspect of the present disclosure is to provide a substrate including a nanotwin metal layer and a printed circuit board that can easily respond to implement a fine pitch in components such as microbumps and provide better reliability.

An aspect of the present disclosure is to form a nanotwin metal such as nanotwin copper, based on a seed layer including a crystal structure which is preferably not oriented on a (111) plane, and to apply the formed metal layer to a wiring layer of a printed circuit board, or the like.

For example, according to an aspect of the present disclosure, a substrate including a nanotwin metal layer may include a substrate, a seed layer disposed on the substrate, and a nanotwin metal layer disposed on the seed layer, wherein the seed layer may include a crystal structure having a random orientation, a crystal structure having a preferred orientation on a (200) plane, and/or a crystal structure having a preferred orientation on a (220) plane.

For example, according to an aspect of the present disclosure, a printed circuit board may include an insulating layer and a wiring layer disposed on the insulating layer, and the wiring layer may include a seed layer and a metal layer disposed on the seed layer, wherein the seed layer may include an electrolytic copper foil, a rolled copper foil, an electrolytic copper layer, an electroless copper layer, an electrolytic nickel layer and/or an electroless nickel layer, and the metal layer may include nanotwin copper.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a substrate including a nanotwin metal layer;

FIG. 4 is a cross-sectional view schematically illustrating an example of a printed circuit board; and

FIGS. 5 to 7 schematically illustrate cross-sectional images of nanotwin copper, respectively.

### DETAILED DESCRIPTION

Hereinafter, the present disclosure will be described with reference to the attached drawings. In the drawings, the shapes and sizes of elements may be exaggerated or reduced for clarity of explanation.

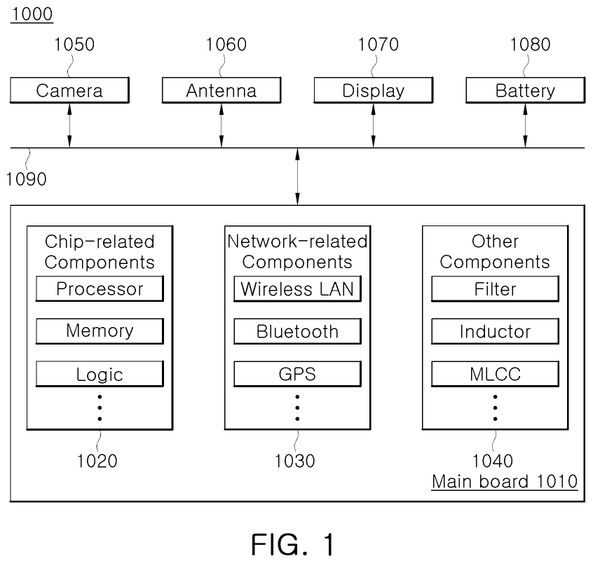

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other. The chip related components 1020 may be in the form of a package including the chip or electronic component described above.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

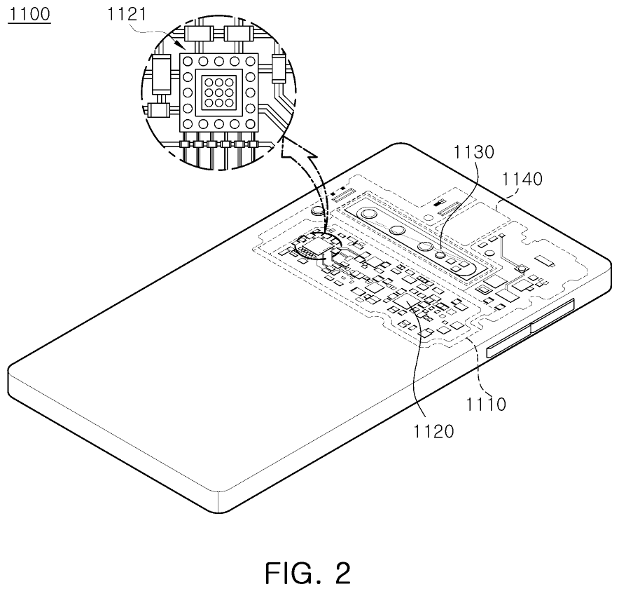

FIG. 2 is a perspective diagram illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. Meanwhile, the electronic device is not necessarily limited to the smartphone 1100, and may be other electronic devices as described above.

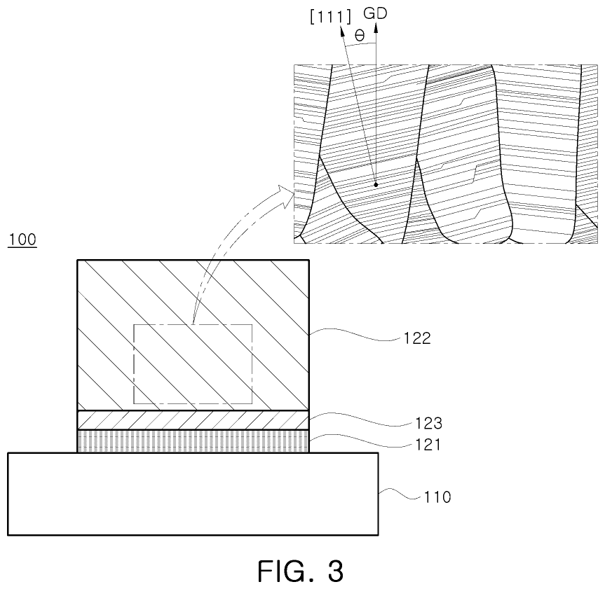

FIG. 3 is a cross-sectional diagram schematically illustrating an example of a substrate including a nanotwin metal layer.

Referring to FIG. 3, a multilayer substrate 100 including a nanotwin metal layer according to an example may include a substrate 110, a seed layer 121 disposed on the substrate 110, and a nanotwin metal layer 122 disposed on the seed layer 121. The multilayer substrate 100 may include an organic insulating layer including an organic material such as epoxy or polyimide, but an embodiment thereof is not limited thereto, and may include an inorganic insulating layer including an inorganic material such as silicon (Si) as needed. The seed layer 121 may include copper having a crystal structure which is preferably not oriented on a (111) plane. For example, the seed layer 121 may include a crystal structure having a random orientation, a crystal structure having a preferred orientation on a (200) plane, and/or a crystal structure having a preferred orientation on a (220) plane. The seed layer 121 including such a crystal structure may include, for example, an electrolytic copper foil, a rolled copper foil, an electrolytic copper layer, an electroless copper layer, an electrolytic nickel layer, and/or an electroless nickel layer. The nanotwin metal layer 122 may include a nanotwin metal, for example, nanotwin copper. The nanotwin copper may include a plurality of columnar grains, and at least a portion of the plurality of columnar grains may include nanotwin. A transition layer 123 may be disposed in a boundary region between the seed layer 121 and the nanotwin metal layer 122. The transition layer 123 may include a portion of the seed layer 121 and a portion of an initial growth layer of the nanotwin metal layer 122. The transition layer 123 may be formed to a thickness within 20% of a thickness of the nanotwin metal layer 122, but an embodiment thereof is not limited thereto.

Meanwhile, the crystal structure having a random orientation may mean a state in which crystal grains are not aligned in a specific direction in a polycrystalline metal or thin film structure in a specific direction, but are randomly distributed in all directions. This can occur when each crystal grain is arranged independently of others thereof in a metal structure and no preferred orientation appears. For example, there may not be a dominant orientation of a particular plane, and the orientations of all crystal grains may be distributed independently. This can be measured using a X-ray diffraction (XRD), pole figures, a selected area electron diffraction (SAED), an electron backscatter diffraction (EBSD), etc. For example, in the X-ray diffraction (XRD) data, a peak intensity of each diffraction plane can roughly match or be similar to a relative intensity ratio in an ideal polycrystalline sample. To quantitatively evaluate this, a texture coefficient may be calculated, and the texture coefficient of all planes may have a value close to approximately 1. Alternatively, the intensity may be distributed uniformly in a pole figure. Alternatively, the orientation may be distributed in various directions in the electron diffraction (SAED or EBSD), and there may be no apparent dominance in a particular direction.

In addition, the crystal structure having a preferred orientation on an (200) plane may mean a state in which a specific crystal plane, the (200) plane, is preferred or primarily aligned over other planes in a polycrystalline metal or thin film structure. This can occur when a lattice plane represented by a Miller index (200) in a metal crystal structure is preferentially grown or oriented by specific process conditions, energy states, or interactions with the substrate. The crystal orientation can be measured using s X-ray diffraction (XRD), pole figure, a selected area electron diffraction (SAED), an electron backscatter diffraction (EBSD), etc. For example, the preferred orientation on the (200) plane may be confirmed through the fact that the intensity of the (200) peak is relatively more prominent than that of other peaks in the X-ray diffraction (XRD) data. To quantitatively evaluate this, a texture coefficient may be calculated, and when the texture coefficient of the (200) plane is relatively large as compared to that of other planes, for example, 1.5 or more, it can be determined that the (200) plane has a preferred orientation. Alternatively, the orientation may be confirmed by analyzing a diffraction radius and intensity of the (200) plane in the pole figure. Alternatively, the preferred orientation may be confirmed by analyzing the fraction and orientation distribution of crystal grains with the (200) plane orientation in electron diffraction (SAED or EBSD).

In addition, the crystal structure having a preferred orientation on a (220) plane may mean a state in which a specific crystal plane, the (220) plane, is preferred or primarily aligned over other planes in a polycrystalline metal or thin film structure. This can occur when a lattice plane represented by a Miller index (220) in a metal crystal structure is preferentially grown or oriented by specific process conditions, energy states, or interactions with the substrate. This can be measured using X-ray diffraction (XRD), pole figure, selected area electron diffraction (SAED), electron backscatter diffraction (EBSD), etc. For example, the preferred orientation of the (220) plane may be confirmed through the fact that the intensity of the (220) peak is relatively more prominent than that of other peaks in the X-ray diffraction (XRD) data. To quantitatively evaluate this, a texture coefficient may be calculated, and when a texture coefficient of the (220) plane is relatively large compared to that of other planes, for example, 1.5 or more, it can be determined that the (220) plane has a preferred orientation. Alternatively, the orientation may be confirmed by analyzing a diffraction radius and intensity of the (220) plane in the pole figure. Alternatively, the preferred orientation may be confirmed by analyzing the fraction and orientation distribution of crystal grains with the (220) plane orientation in electron diffraction (SAED or EBSD).

As described above, the multilayer substrate 100 including the nanotwin metal layer according to an example may include a seed layer 121 including copper, nickel, etc. that may be used for a printed circuit board, such as a package substrate, and such a seed layer 121 may include a crystal structure which is preferably not oriented on the (111) plane as described above. For example, when measuring and analyzing a crystal orientation state of the seed layer 121 using selected area electron diffraction (SAED), both (111) and other (hkl) planes may illustrate ring patterns of similar intensity, and in this case, it may be difficult to see that the (111) plane is predominantly oriented. Meanwhile, when the (111) plane is strongly oriented, the (111) plane may appear as a partial ring shape or a dot shape, and other (hkl) planes may appear as partial ring shapes with relatively low intensity, or the like. As described above, when the seed layer 121 includes a crystal structure which is preferably not oriented on the (111) plane, a [111] direction of at least one columnar grain including nanotwin of nanotwin copper included in the nanotwin metal layer 122 may be inclined at an angle (θ) greater than 0 degrees and less than or equal to 25 degrees with respect to a growth direction GD. When such a nanotwin metal layer 122 is applied to a wiring of a fine pitch, a rewiring, a pad, microbumps, or the like of a package substrate, reliability may be expected to be improved by suppressing the occurrence or growth of Kirkendall voids, or the like, during processes such as thermocompression bonding. For example, such a nanotwin copper structure may have multiple triple points at which a twin boundary and a grain boundary meet, which can hinder the movement of vacancies, thereby inhibiting the occurrence or growth of Kirkendall voids, or the like.

Meanwhile, the nanotwin metal layer 122 may have a content of nanotwin copper on the (111) plane of 80% or more and less than 100% in the cross-section and 90% or more and less than 100% on the surface. In addition, the nanotwin metal layer 122 may have a thickness of about 1 μm to 10 μm, or about 1 μm to 5 μm, and a size of at least one columnar grain including nanotwin of nanotwin copper included therein may also be about 1 μm to 10 μm, or about 1 μm to 5 μm. However, an embodiment thereof is not necessarily limited thereto.

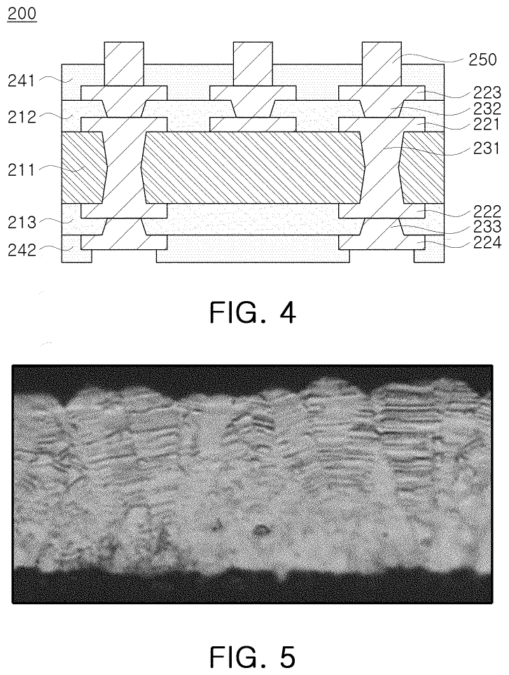

FIG. 4 is a cross-sectional view schematically illustrating an example of a printed circuit board.

Referring to FIG. 4, a printed circuit board 200 according to an example may be a multilayer board structure including a plurality of insulating layers 211, 212, 213, 241, and 242, a plurality of wiring layers 221, 222, 223, 224, and 250, and a plurality of via layers 231, 232, and 233. For example, the printed circuit board 200 according to the example may be a package board, but an embodiment thereof is not limited thereto. One or more wiring layers of the plurality of wiring layers 221, 222, 223, 224, and 250 may include the seed layer 121, the nanotwin metal layer 122, and the transition layer 123 described in the multilayer substrate 100 including the nanotwin metal layer according to the above-described example. For example, one or more wiring layers of the plurality of wiring layers 221, 222, 223, 224, and 250 may include a seed layer including one or more of an electrolytic copper foil, a rolled copper foil, an electrolytic copper layer, an electroless copper layer, an electrolytic nickel layer, and an electroless nickel layer, and a metal layer disposed on the seed layer and including nanotwin copper, respectively. In addition, a transition layer disposed therebetween may be further included, respectively.

For example, the seed layer may include a crystal structure which is preferably not oriented on the (111) plane. In addition, the nanotwin copper may include a plurality of columnar grains, and at least a portion of the plurality of columnar grains may include nanotwin. In addition, a [111] direction of at least one columnar grain including nanotwin of nanotwin copper may be inclined at an angle of greater than 0 degrees and less than or equal to 25 degrees with respect to a growth direction. Meanwhile, one or more wiring layers of the plurality of wiring layers 221, 222, 223, 224, and 250 may include one or more of a wiring, rewiring, pad, and/or microbump including the seed layer, the metal layer, and the transition layer. Meanwhile, a more specific description of the seed layer, the metal layer, and the transition layer may be substantially the same as that described for the multilayer substrate 100 including the nanotwin metal layer according to the above-described example.

Hereinafter, components of a printed circuit board 200 according to an example will be described in more detail with reference to the drawings.

A substrate including a plurality of insulating layers 211, 212, 213, 241, and 242, a plurality of wiring layers 221, 222, 223, 224, and 250, and a plurality of via layers 231, 232, and 233 may be a multilayer substrate of a core type. The substrate may include a core insulating layer 211, first and second core wiring layers 221 and 222 respectively disposed on an upper surface and a lower surface of the core insulating layer 211, a core via layer 231 penetrating the core insulating layer 211 and connecting the first and second core wiring layers 221 and 222, one or more first build-up insulating layers 212 disposed on an upper surface of the core insulating layer 211, one or more first build-up wiring layers 223 respectively disposed on or within the one or more first build-up insulating layers 212, one or more first build-up via layers 232 respectively penetrating one or more of the one or more first build-up insulating layers 212, one or more second build-up insulating layers 213 disposed on a lower surface of the core insulating layer 211, one or more second build-up wiring layers 224 respectively disposed on or within the one or more second build-up insulating layers 213, one or more second build-up via layers 233 respectively penetrating one or more of the one or more second build-up insulating layers 213, a first outermost insulating layer 241 disposed on a first build-up insulating layer 212 disposed on the uppermost side of one or more first build-up insulating layers 212, a second outermost insulating layer 242 disposed on a second build-up insulating layer 213 disposed on the lowermost side of one or more second build-up insulating layers 213, and an outermost wiring layer 250 disposed on a first build-up wiring layer 223 disposed on the uppermost side of one or more first build-up wiring layers 223, and at least a portion of which is covered by the first outermost insulating layer 241 and at least another portion of which protrudes onto the first outermost insulating layer 241. However, the present disclosure is not limited thereto, and the multilayer substrate may be a coreless-type multilayer substrate. In addition, the multilayer substrate may be a multilayer substrate having a hybrid structure including both a core-type substrate portion and a coreless-type substrate portion.

The core insulating layer 211 may include an organic insulating material. The organic insulating material may include a thermosetting resin such as epoxy resin, a thermoplastic resin such as polyimide, or a material in which these insulating resins are mixed with an inorganic filler such as silica, or the like, or a resin impregnated into a core material such as glass fiber (glass cloth, glass fabric), or the like, together with the inorganic filler, for example, an insulating material such as copper clad laminate (CCL), or the like, but the present disclosure is not limited thereto. The core insulating layer 211 may be thicker than each of the one or more first and second build-up insulating layers 212 and 213, but the present disclosure is not limited thereto.

Each of the first and second build-up insulating layers 212 and 213 may include an insulating material. The insulating material may include a thermosetting resin such as an epoxy resin, a thermoplastic resin such as polyimide, or a material in which these insulating resins are mixed with an inorganic filler such as silica, or the like, or a resin impregnated into a core material such as glass fiber, or the like, together with the inorganic filler, for example, an insulating material such as Ajinomoto Build-up Film (ABF), prepreg, resin coated copper (RCC), or the like, but the present disclosure is not limited thereto. Each of the first and second build-up insulating layers 212 and 213 may be formed as a plurality of layers. In this case, the number of layers of each of the first and second build-up insulating layers 212 and 213 is not particularly limited, and the first and second build-up insulating layers 212 and 213 may have the same number of layers, but the present disclosure is not limited thereto.

Each of the first and second core wiring layers 221 and 222 may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu). Each of the first and second core wiring layers 221 and 222 may include a seed layer and a metal layer formed on the seed layer by plating. The seed layer may be a rolled copper foil or an electrolytic copper foil of a Copper Clad Laminate (CCL). Alternatively, the seed layer may be formed by electroless copper plating or electroless nickel plating. If necessary, the seed layer may also be formed by electrolytic nickel plating. The metal layer may be formed by electrolytic plating. Alternatively, the metal layer may be formed by plating for forming the nanotwin copper described above. Each of the first and second core wiring layers 221 and 222 may perform various functions depending on the design of each layer. For example, each of the first and second core wiring layers 221 and 222 may include a ground pattern, a power pattern, a signal pattern, and the like. Each of the patterns may include various forms such as a line, a plain, and/or a pad.

Each of the first and second build-up wiring layers 223 and 224 may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu). Each of the first and second build-up wiring layers 223 and 224 may include a seed layer and a metal layer formed on the seed layer by plating. The seed layer may be a rolled copper foil or an electrolytic copper foil of a Resin Clad Copper (RCC). Alternatively, the seed layer may be formed by electroless copper plating or electroless nickel plating. If necessary, the seed layer may also be formed by electrolytic nickel plating. The metal layer may be formed by electrolytic plating. Alternatively, the metal layer may be formed by plating for forming the nanotwin copper described above. Each of the first and second build-up wiring layers 223 and 224 may perform various functions depending on the design of each layer. For example, each of the first and second build-up wiring layers 223 and 224 may include a ground pattern, a power pattern, a signal pattern, and the like. Each of the patterns may include various forms such as a line, a plain, and/or a pad. Each of the first and second build-up insulating layers 223 and 224 may be formed as a plurality of layers. In this case, the number of layers of each of the first and second build-up insulating layers 223 and 224 is not particularly limited, and the first and second build-up insulating layers 223 and 224 may have the same number of layers, but the present disclosure is not limited thereto.

The core via layer 231 may include a through-via. The through-via may include a metal layer filling at least a portion of the through-hole. The through-via may include a metal. The metal may include at least one selected from the group consisting of copper (Cu), aluminum (Al), silver (Ag), tin (Sn), gold (Au), nickel (Ni), lead (Pb), titanium (Ti), and alloys thereof. Preferably, the metal may include copper (Cu). The through-via may include a seed layer formed on a wall surface of the through-hole and a metal layer formed on the seed layer by plating. The seed layer may be formed by electroless copper plating or electroless nickel plating. If necessary, the seed layer may also be formed by electrolytic nickel plating. The metal layer may be formed by electrolytic plating. Alternatively, the metal layer may be formed by plating for forming the nanotwin copper described above. The through-via may perform various functions depending on the design of each layer. For example, the through-via may include a ground via, a power via, a signal via, and the like. The through-via may have a substantially hourglass shape or a cylindrical shape. The through-via may be provided in plural.

Each of the first and second build-up via layers 232 and 233 may include a connection via. The connection via of each of the first and second build-up via layers 232 and 233 may be a filled VIA filling a via hole or a conformal VIA disposed along a wall surface of the via hole. The connection via of each of the first and second build-up via layers 232 and 233 may be disposed in a stacked type and/or staggered type. The connection via of each of the first and second build-up via layers 232 and 233 may include a metal, and the metal may include at least one selected from the group consisting of copper (Cu), aluminum (Al), silver (Ag), tin (Sn), gold (Au), nickel (Ni), lead (Pb), titanium (Ti), and alloys thereof. Preferably, the metal may include copper (Cu). The connection via of each of the first and second build-up via layers 232 and 233 may include a seed layer formed on a wall surface of a through-hole formed on a wall surface of a via hole and a metal layer formed on the seed layer by plating. The seed layer may be formed by electroless copper plating or electroless nickel plating. If necessary, the seed layer may also be formed by electrolytic nickel plating. The metal layer may be formed by electrolytic plating. Alternatively, the metal layer may be formed by plating for forming the nanotwin copper described above. The connection via of each of the first and second build-up via layers 232 and 233 may perform various functions depending on the design of each layer. For example, the through-via may include a ground via, a power via, a signal via, and the like. The connection via of each of the first and second build-up via layers 232 and 233 may have a substantially tapered shape, for example, may have a shape tapered in opposite directions. The connection via of each of the first and second build-up via layers 232 and 233 may be provided in plural. Each of the first and second build-up via layers 232 and 233 may be a plurality of layers. In this case, the number of layers of each of the first and second build-up via layers 232 and 233 is not particularly limited, and the first and second build-up via layers 232 and 233 may may have the same number of layers, but an embodiment thereof is not limited thereto.

Each of the first and second outermost insulating layers 141 and 142 may include an organic insulating material. The organic insulating material may include a thermosetting resin such as an epoxy resin, a thermoplastic resin such as polyimide, or a material in which these insulating resins are mixed with an inorganic filler such as silica, or the like, for example, an insulating material such as Ajinomoto Build-up Film (ABF) or Solder Resist (SR) may be used, but the present disclosure is not limited thereto. The first and second outermost insulating layers 141 and 142 may be disposed on the uppermost and lowermost sides of the substrate to protect the internal configuration. If necessary, the second outermost insulating layer 142 may have a plurality of openings of a Solder Mask Defined (SMD) and/or Non-Solder Mask Defined (NSMD) type.

The outermost wiring layer 150 may include microbumps. The microbumps may have a pillar shape, but the present disclosure is not limited thereto. The microbumps may include a metal. The metal may include at least one selected from the group consisting of copper (Cu), aluminum (Al), silver (Ag), tin (Sn), gold (Au), nickel (Ni), lead (Pb), titanium (Ti), and alloys thereof. Preferably, the metal may include copper (Cu). The microbump may include a seed layer and a metal layer formed on the seed layer by plating. The seed layer may be formed by electroless copper plating or electroless nickel plating. If necessary, the seed layer may also be formed by electrolytic nickel plating. The metal layer may be formed by electrolytic plating. Alternatively, the metal layer may be formed by plating for forming the nanotwin copper described above. The microbump may perform various functions depending on the design of each layer. For example, the microbump may include a ground via, a power via, a signal via, and the like. The microbump may be provided in plural.

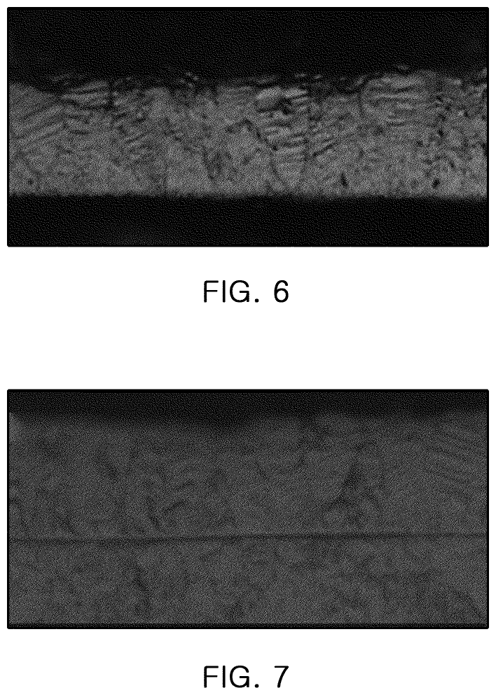

FIGS. 5 to 7 schematically illustrate cross-sectional images of nanotwin copper, respectively.

FIG. 5 may be a cross-sectional image of a case in which nanotwin copper is formed on a rolled copper foil. Such a cross-sectional image may be obtained by photographing a cross-section of a nanotwin metal layer using an electron microscope, such as a Scanning Electron Microscope (SEM), TEM (Transmission Electron Microscope), etc. Meanwhile, the rolled copper foil may be a copper foil of Copper Clad Laminate (CCL) used as a core layer in a printed circuit board. Referring to FIG. 5, nanotwin copper may also be well formed on such a rolled copper foil. In addition, in this case, a [111] direction of a columnar grain of the formed nanotwin copper may be inclined to a growth direction. Therefore, the above-described technical effect may be achieved. Such a cross-sectional image may be applied to the nanotwin metal layer 100 and/or printed circuit board 200.

FIG. 6 may be a cross-sectional image of a case in which nanotwin copper is formed on an electrolytic nickel layer, which may also be obtained by photographing a cross-section of a nanotwin metal layer using an electron microscope as described above. Referring to FIG. 6, nanotwin copper may also be well formed on an electrolytic nickel layer that can be used for a package substrate, etc., and a [111] direction of a columnar grain of the nanotwin copper may be inclined to a growth direction. Therefore, the technical effect described above may be obtained. Such a cross-sectional image may also be applied to the nanotwin metal layer 100 and/or printed circuit board 200 described above.

FIG. 7 may be a cross-sectional image of a case in which nanotwin copper is formed on an electroless copper layer, for example, on a chemical copper layer, which may also be obtained by photographing a cross-section of the nanotwin metal layer using an electron microscope as described above. Referring to FIG. 7, nanotwin copper may be well formed on an electroless copper layer, for example, on a chemical copper layer, which may be used as a seed layer for forming a circuit of a printed circuit board, and a direction of a columnar grain of the nanotwin copper may be inclined to a growth direction. Therefore, the technical effect described above may be obtained. Such a cross-sectional image may also be applied to the nanotwin metal layer 100 and/or printed circuit board 200 described above.

In the present disclosure, the term “covering” may include a case of covering at least partially as well as a case of covering completely, and may also include a case of covering not only directly but also indirectly. Moreover, the term “filling” may include a case of completely filling but also a case of at least partially filling, and may also include a case of approximately filling. For example, the term “filling” may include a case in which, for example, some pores or voids exist. Further, the term “surrounding” may include not only a case of completely surrounding but also a case of partially surrounding, and a case of approximately surrounding. Also, the term “exposing” may include exposing partially as well as exposing completely, and “exposing” may refer to exposing from embedding a corresponding component. For example, exposing a pad by an opening may be exposing the pad from an outermost insulating layer, and a surface treatment layer or the like may be further disposed on the exposed pad.

In the present disclosure, determination may be performed by including process errors, positional deviations, errors at the time of measurement, which may occur substantially in a manufacturing process. For example, being disposed on substantially the same level may include not only a case of being disposed in completely the same position, but also a case of being disposed in approximately the same position. Also, being substantially tapered may include not only a completely tapered shape but also an approximately tapered shape, for example, it may be determined by the overall shape.

In the present disclosure, the meaning on a cross-section may mean a cross-sectional shape when an object is vertically cut, or a cross-sectional shape when the object is viewed from the side. Also, the meaning on a plane may refer to a planar shape when the object is horizontally cut, or a planar shape when the object is viewed from the top or the bottom.

In the present disclosure, the terms “a lower side, a lower portion, a lower surface, the other surface”, and the like, are used to refer to a downward direction based on the cross-section of the drawing for convenience, and the terms “an upper side, an upper portion, an upper surface, one surface,” and the like, are used as the opposite directions. However, this is a definition of direction for the convenience of explanation, and the scope of the claim is not specifically limited by the description of this direction, and the concept of upper/lower may be changed at any time.

In the present disclosure, the term “connected” may not only refer to “directly connected” but also include “indirectly connected” may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from another, and may not limit a sequence and/or an importance, or others, in relation to the elements. In some cases, a first element may be referred to as a second element, and similarly, a second element may be referred to as a first element without departing from the scope of right of the example embodiments.

In the present disclosure, a crystal structure, thickness, etc. may be measured based on a cross-section of the printed circuit board, which is polished or cut, respectively. For example, after obtaining a sample including a cut cross-section, necessary experiments may be conducted based on the sample. The cut cross-section may be a vertical cross-section or a horizontal cross-section, and each value can be measured based on the required cut cross-section. Meanwhile, when measuring a value, if the value is not constant, the value may be determined as an average value of the values measured at five random points.

In the present disclosure, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as being relevant to the other example embodiment unless otherwise indicated.

The terms used herein describe particular embodiments only, and the present disclosure is not limited thereby. As used herein, the singular forms “a,” “an,” and “the” are intended to include the plural forms as well, unless the context clearly indicates otherwise.

According to the aforementioned embodiments, a substrate including a nanotwin metal layer and a printed circuit board that can easily correspond to implement a fine pitch in components such as microbumps and provide better reliability, may be provided.

While the example embodiments have been illustrated and described above, it will be apparent to those skilled in the art that modifications and variations could be made without departing from the scope of the present disclosure as defined by the appended claims.

What is claimed is:

1. A multilayer substrate including a nanotwin metal layer, comprising:
a substrate;
a seed layer disposed on the substrate; and
a nanotwin metal layer disposed on the seed layer,
wherein the seed layer includes at least one selected from the group consisting of a crystal structure having a random orientation, a crystal structure having a preferred orientation on a (200) plane, and a crystal structure having a preferred orientation on a (220) plane.

2. The multilayer substrate including a nanotwin metal layer of claim 1, wherein the seed layer includes at least one selected from the group consisting of an electrolytic copper foil, a rolled copper foil, an electrolytic copper layer, an electroless copper layer, an electrolytic nickel layer, and an electroless nickel layer.

3. The multilayer substrate including a nanotwin metal layer of claim 1, wherein the nanotwin metal layer includes nanotwin copper.

4. The multilayer substrate including a nanotwin metal layer of claim 3, wherein the nanotwin copper comprises a plurality of columnar grains, and
at least a portion of the plurality of columnar grains include nanotwin.

5. The multilayer substrate including a nanotwin metal layer of claim 4, wherein a [111] direction of at least one of the plurality of columnar grains including the nanotwin of the nanotwin copper is inclined at an angle greater than 0 degrees and less than or equal to 25 degrees with respect to a growth direction.

6. The multilayer substrate including a nanotwin metal layer of claim 3, wherein the nanotwin metal layer has a content of nanotwin copper on a (111) plane of 80% or more and less than 100% in the cross-section and 90% or more and less than 100% on the surface.

7. The multilayer substrate including a nanotwin metal layer of claim 3, wherein the nanotwin metal layer has a thickness of 1 μm to 10 μm.

8. The multilayer substrate including a nanotwin metal layer of claim 1, further comprising:
a transition layer disposed in a boundary region between the seed layer and the nanotwin metal layer, and including a portion of each of the seed layer and the nanotwin metal layer.

9. The multilayer substrate including a nanotwin metal layer of claim 1, wherein the substrate is an insulating layer including an organic insulating material.

10. A printed circuit board, comprising:
an insulating layer; and
a wiring layer disposed on the insulating layer,
wherein the wiring layer includes a seed layer including at least one selected from the group consisting of an electrolytic copper foil, a rolled copper foil, an electrolytic copper layer, an electroless copper layer, an electrolytic nickel layer, and an electroless nickel layer, and
a metal layer disposed on the seed layer, and including nanotwin copper.

11. The printed circuit board of claim 10, wherein the seed layer includes a crystal structure, which is preferably not oriented on a (111) plane.

12. The printed circuit board of claim 10, wherein the nanotwin copper includes a plurality of columnar grains, and
at least a portion of the plurality of columnar grains include nanotwin.

13. The printed circuit board of claim 12, wherein a [111] direction of at least one of the plurality of columnar grains including the nanotwin of the nanotwin copper is inclined at an angle greater than 0 degrees and less than or equal to 25 degrees with respect to a growth direction.

14. The printed circuit board of claim 10, wherein the wiring layer further includes a transition layer disposed in a boundary region between the seed layer and the metal layer, and including a portion of each of the seed layer and the metal layer.

15. The printed circuit board of claim 10, wherein the wiring layer includes one or more of a wiring, a rewiring, a pad, and a microbump, each of which includes the seed layer and the metal layer.
